(19) United States
(12) Patent Application Publication
(10) Pub. No.: US 2009/0091400 A1
(43) Pub. Date: Apr. 9, 2009

(54) Method and Apparatus for Generating Dynamically Varying Time Hopping Sequences for UWB Signals

(76) Inventors: Philip V. Orlik, Cambridge, MA (US); Andreas F. Molisch, Arlington, MA (US); Zafer Sahinoglu, Arlington, MA (US)

Correspondence Address: MITSUBISHI ELECTRIC RESEARCH LABORATORIES, INC., 201 BROADWAY, 8TH FLOOR, CAMBRIDGE, MA, 02139, US

(21) Appl. No.: 12/160,168

(22) PCT Filed: Jan. 11, 2006
(86) PCT No.: PCT/US06/00717

§ 371 Date: Jul. 7, 2008

(51) Int. Cl. H03C 3/00; H03K 7/04

(52) U.S. Cl. 332/103; 332/112

(57) ABSTRACT

A method and apparatus modulate a polarity of a burst of pulses of the impulse radio signal using a first pseudo noise sequence generated by a shift register and a position of the burst of pulses using a second pseudo noise sequence generated by the shift register.

### FIELD OF THE INVENTION

This invention relates generally to spread spectrum radio communication systems, and more particularly to modulation formats used in wireless communication systems that enable signal reception by both coherent and non-coherent ultra-wideband receivers.

### BACKGROUND OF THE INVENTION

In the United States, the Federal Communications Commission (FCC) allows a restricted unlicensed use of ultra-wide band width (UWB) signals for wireless communication systems, “First Report and Order,” Feb. 14, 2002. The UVB signals must be in the frequency range from 3.1 to 10.6 GHz, and have a minimum band width of 500 MHz. The FCC order limits the power spectral density and peak emissions power of the UWB signals, e.g. less than −43.1 dBm/MHz.

One modulation method for UWB uses extremely short time pulses to generate signals with band widths greater than 500 MHz, e.g., 1/1,000,000,000 of a second of less, which corresponds to a wavelength of about 600 mm. Systems that use short pulses are commonly referred to as impulse radio (IR) systems.

As shown in FIG. 1, four different modulation formats can be used for wireless communication systems, pulse position modulation (PPM) 11, pulse amplitude modulation (PAM) 12, on-off keying (OOK) 13, and bi-phase shift keying (BPSK) 14.

As an advantage, UWB systems achieve high data rates, and are resistant to multi-path impairments due to large processing gains. Additionally, IR based UWB technology allows for the implementation of low cost, low duty cycle, low power transceivers that do not require local oscillators for heterodyning. Because UWB transceivers are primarily digital circuits, the transceivers can easily be integrated in semiconductor circuits. In UWB systems, multiple users can concurrently share the same spectrum with no interference to one another. UWB systems are ideal for high-speed home and business networking devices, as well as sensor networks.

Time hopping, impulse radio (TH-IR) system are described by M. Win et al., “Ultra-Wide Band Width Time-Hopping Spread-Spectrum Impulse Radio for Wireless Multiple-Access Communications,” IEEE Trans. On Communications, Vol. 48, No. 4, pp. 679-691, April 2000. In a TH-IR system, each bit or symbol is represented by N_{f} pulses, where N_{f} is a positive integer. The time to transmit the symbol is Tₛ. This is called the symbol duration. The symbol time Tₛ is further partitioned into frames T_{f}, and the frames are partitioned into chips Tₛ corresponding typically to a pulse duration. If N_{c} represents the number of chips in a frame and N_{f} represents the number of frames in a symbol, then Tₛ, T_{f} and T_{c} are related as follows

Tₛ=N_{f}T_{f}=N_{f}N_{c}T_{c}. (1)

FIG. 2 shows a relationship between the symbol time Tₛ 201, the frame time T_{f} 202, and the chip time t_{c} 203 for pulses 204 for an example prior art TH-IR waveform 210 for a ‘0’ bit, and a waveform 220 for a ‘1’ bit. Typically, the pulses are spaced pseudo-randomly among the available chips in a frame according to a “time-hopping” sequence to minimize the effect of multi-user interference.

As stated above, the modulation can be binary phase shift keying. With BPSK, each bit b is represented as either a positive or negative pulse, i.e., b E {−1,1}. The transmitted signal s at time t has a form

$$s ( t ) = {\sum }_{i = 1}^{∞} {\sum }_{j = 1}^{{N}_{f}} {h}_{i , j} {b}_{⌊ i / {N}_{f} ⌋} p ( t - {jT}_{f} - {c}_{j} {T}_{c} ) , \qquad ( 2 )$$

where cⱼ represents the j^{th} value of the TH code, in the range {0, 1, . . . , N_{c}−1}, and b is the i^{th} modulation symbol. Additionally, an optional polarity scrambling sequence, denoted as h_{i,j}, can be applied to each pulse in the transmitted signal to shape the spectrum of the transmitted signal and to reduce spectral lines. The polarity scrambling sequence h_{i,j} has values of either +1 or −1. Different amplitudes are possible to shape of the spectrum of the transmitted signal.

In addition to the modulation methods described above, phase and position modulation, e.g., BPSK and binary PPM, can be combined to generate a modulation format suitable for both coherent and non-coherent receivers. This is accomplished by partitioning a symbol duration, Tₛ, into two or more parts to enable position modulation, and furthermore to allow the polarity of individual pulses to vary according to the bits being transmitted, e.g., BPSK. This is in fact the modulation technique described by the IEEE P802.15 Working Group for Wireless Personal Area Networks (WPANs) task group and is described in “Addendum PART 15.4: Wireless Medium Access Control (MAC) and Physical Layer (PHY) Specifications for Low-Rate Wireless Personal Area Networks (LR-WPANs)” (Internet Draft, Document Number 15-05-0733-01-004a, incorporated herein by reference.

### SUMMARY OF THE INVENTION

A method and apparatus modulate a polarity of a burst of pulses of the impulse radio signal using a first pseudo noise sequence generated by first taps of a shift register and a position of the burst of pulses using a second pseudo noise sequence generated by seconds taps of the shift register.

### BRIEF DESCRIPTION OF THE DRAWINGS

FIG. 1 is a timing diagram of prior art modulation techniques;

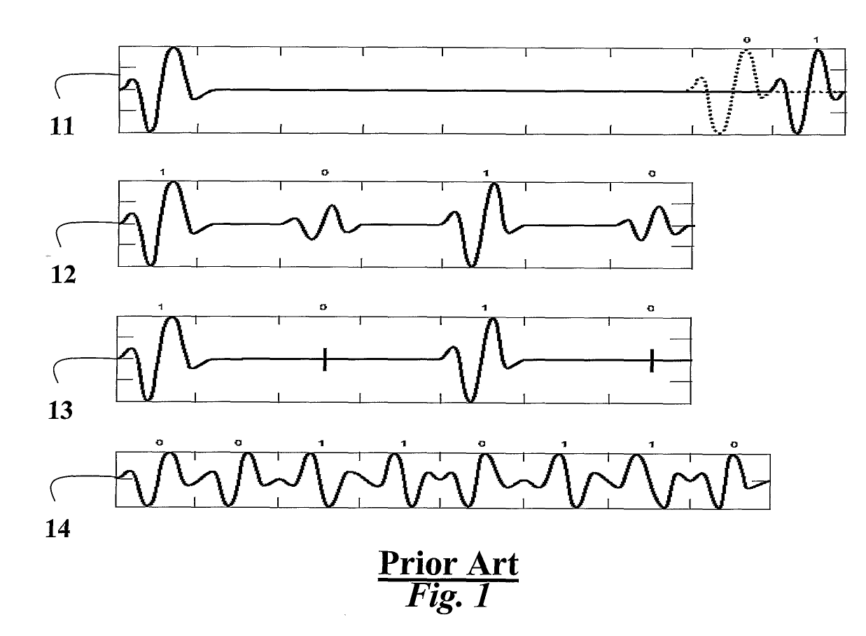

FIG. 2 is a timing diagram of prior art TH-IR modulation;

FIG. 3 is timing diagram of a prior art burst hopping IR modulation;

FIG. 4 is a block diagram of the transmitter structure according to an embodiment of the invention; and

FIG. 5 is a diagram of a PN sequence generator for the transmitter of FIG. 4.

### DETAILED DESCRIPTION OF THE PREFERRED EMBODIMENT

One embodiment of our invention provides a system and method for generating both a polarity scrambling sequence, and a time-hopping sequence in an ultra wide bandwidth (UWB) impulse radio (IR) transmitter. The transmitter modulates input data using both pulse position modulation (PPM) and phase shift keying (PSK) modulation. As an advantage, all of the sequences are generated by a single pseudo-noise (PN) sequence generator.

Additionally, a length of the time hopping sequences can be modified dynamically according to modulation format parameters, for example, an average pulse repetition frequency (PRF), and a possible number of hopping position that are available within a modulation waveform, e.g., four or sixteen.

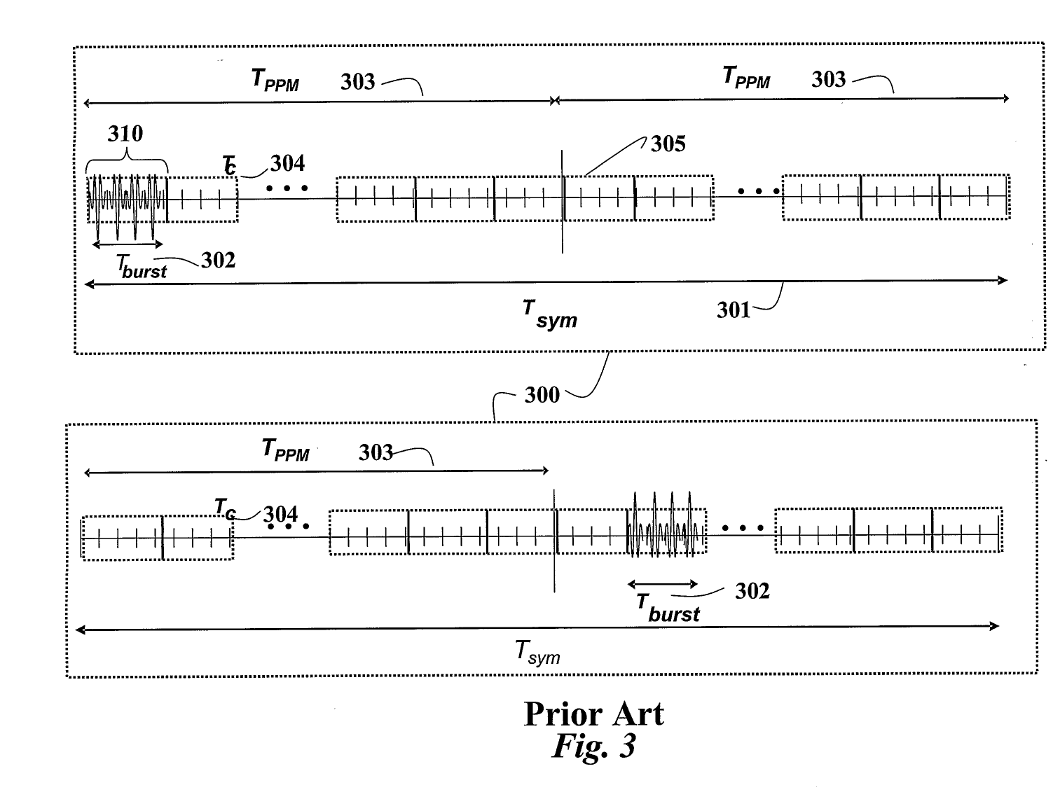

FIG. 3 shows a structure and timing of a modulation symbol. Each symbol 300 includes an integer number N_{c} of chips. Each chip has a duration T_{c}, 304. A total symbol duration is denoted T_{sym} 301, which is equivalent to T_{c}×N_{c}. Furthermore, each symbol duration is partitioned into multiple parts, e.g., two halves 303. In this case, each part has a duration

T_{PPM}=T_{sym}/2,

which enables binary position modulation.

Multiple consecutive chips are grouped together to form a burst of pulses 310. A duration 302 of the pulse burst 310 is denoted as T_{burst}. A position of the burst, in either the first half or the second part of the symbol duration, indicates one bit of information, for example, a logical zero or one.

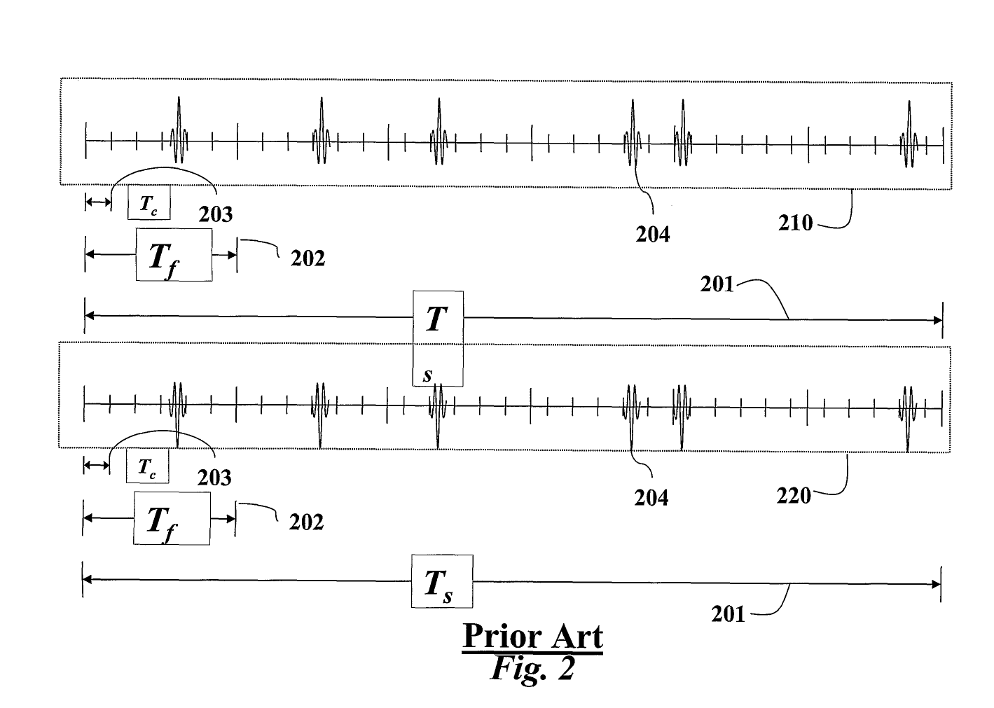

Additionally, a phase of the pulse burst can indicate a second bit of information, or as shown in FIG. 2, the same bit of information is encoded in both the PPM position and the phase of the burst. The upper wave form in FIG. 3 indicates that a ‘0’ bit is being transmitted, while the lower waveform indicates that a ‘1’ bit is being transmitted. During each symbol duration, a single burst is transmitted.

The fact that the duration of the burst of pulses is typically much shorter than the PPM duration, i.e., T_{burst}<<T_{PPM}, minimizes the effect of multi-user interference in this form of time hopping.

The number of possible positions or slots for the pulse burst during each symbol duration is denoted by Nₛₗₒₜ, and is equivalent to T_{PPM}/T_{burst}. The burst positions 305 can vary on a symbol to symbol basis, according to the time hopping sequence. In addition, the possible burst positions are index from 1 to Nₛₗₒₜ.

It is important to contrast the concept of time hopping described according to the embodiment of the invention with the prior art time hopping of Equation (2). In Equation 2, the individual pulse positions within a frame are controlled by the time hopping sequence. In the modulation according to the embodiments of the invention, it is the position of the entire burst of pulses within the PPM duration that is controlled by the time hopping sequence. For convenience, we call our time hopping “pulse burst hopping” in order to differentiate our time hopping from the conventional concept of individual pulse based time hopping.

The k^{th} modulation symbol can be expressed using the following equation

$${x}^{( k )} ( t ) = {\sum }_{j = 1}^{{N}_{burst}} {g}_{1}^{( k )} {s}_{j} p ( t - {g}_{0}^{( k )} {T}_{PPM} - {jT}_{c} - {h}^{( k )} {T}_{burst} ) . \qquad ( 3 )$$

In Equation (3), x^{(k)}(t) is the waveform of the k^{th} symbol, g₀, and g₁ are the modulation symbols obtained from a mapping of encoded bits, sⱼ {j=0, 1, . . . , N_{burst}−1} is the polarity scrambling sequence and takes possible values {−1 or 1}, p(t) is the transmitted pulse shape, T_{PPM} is the duration of the binary pulse position modulation time slot. The time hopping sequence h^{(k)} minimizes multi-user interference, and the polarity scrambling sequence, sⱼ, provides additional interference suppression for coherent receivers, as well as spectral smoothing of the transmitted UWB waveform.

When designing UWB-IR systems, several key parameters of the modulation wave form depend on the average pulse repetition frequency (PRF). The PRF is defined as the number of pulses emitted by the transmitter per second. This parameter is important because the PRF defines the amplitude of the pulses for a fixed transmit power.

According to the modulation scheme defined by Equation (2), the PRF, the symbol duration, the chip duration, the number of pulses per burst, and the PPM order define the number of possible hopping positions. For example given a chip duration T_{c} and a number of pulses per burst, N_{burst} the burst duration is given as

T_{burst}=N_{burst}*T_{c}. (4)

For a given symbol rate T_{sym} and number of pulses per burst N_{burst}, we can determine the average PRF as

PRF=N_{burst}/T_{sym}. (5)

Also from the PPM order, i.e., the number of PPM positions N_{PPM}, we can determine the number of time hopping slots available for positioning the pulse burst. This determination is as follows

$${N}_{slot} = ( {T}_{sym} / {N}_{PPM} ) / {T}_{burst} = \frac{{N}_{burst}}{PRF * {N}_{PPM} * {T}_{burst}} . \qquad ( 6 )$$

Equation (6) indicates that modifying any of the waveform parameters affects the number of slots available for our burst hopping. The PRF can be modified for a given symbol duration or bit rate according to restrictions on the transmitter's clock, or an ability to generate large amplitude pulses.

Another reason for modifying the PRF depends on the type of receiver that is being used to receive the transmitted signals. For example, non-coherent receivers generally have better performance when the PRF is reduced, and a fewer but larger amplitude pulses are transmitted to the receivers.

Therefore, it is desirable to dynamically change the PRF at the transmitter to accommodate different classes of receivers. In addition, due to hardware cost constraints, it is desired to use a single PN-sequence generator for the generation of both the polarity scrambling sequence and the time hopping sequence in a UWB IR.

Due to the adaptive nature of the PRF, and therefore, the number of burst hopping slots, the PN-sequence generator should be capable of supporting a set of time hopping sequences with different lengths, e.g., four or sixteen, or any other integer value.

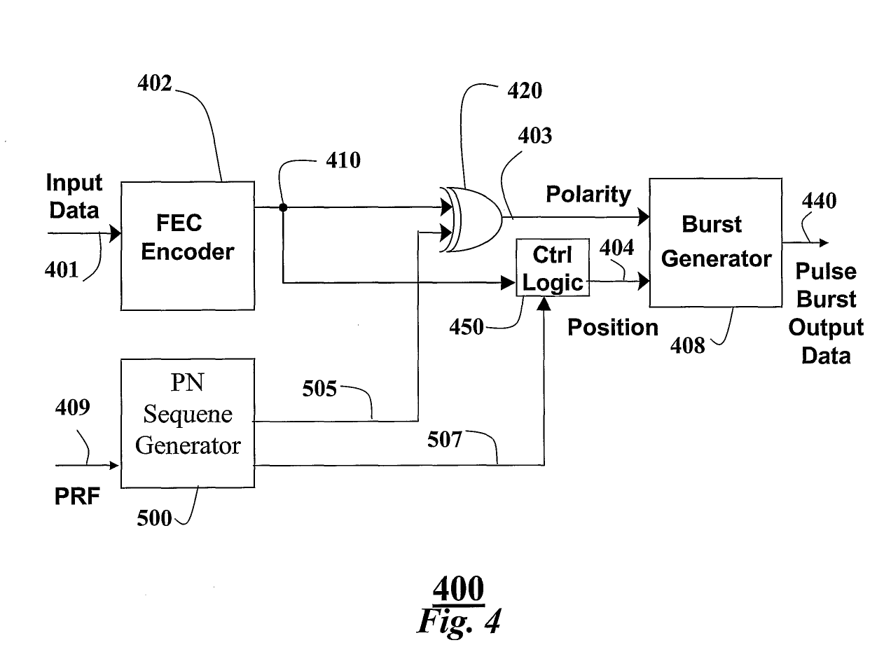

FIG. 4 shows a portion of a transmitter 400 according to an embodiment of the invention. The transmitter uses the combined PPM/BPSK modulation shown in FIG. 3.

Input data 401 are forward error code (FEC) encoded 402. It should be noted that the FEC encoder 402 is optional and not necessary for the invention. The FEC encoder 402 is included in the block diagram of FIG. 4 because FEC is often used in wireless communication systems to provide error correction at the receiver.

An output 410 of the FEC encoder 402 is modulated both in polarity of the entire burst 403 and position 404 for pulse burst output data 440. The polarities of the individual pulses within the burst are then scrambled according PN sequences generated by a single generator 500, depending on a current modulation format.

The single PN sequence generator 500 receives a PRF 409, and outputs a first PN sequence 505 for scrambling the polarity 403, these are equivalent to the Sj's in Equation (3). The polarity 403 of the individual pulses that constitute the burst 440 are scrambled by adding (modulo-2) 420 the encoded pulses 410 with the first PN sequence 505 generated by the PN sequence generator 500. The position 404 of the burst 440, within the PPM duration, is controlled by a second burst hopping sequence 507, a time hopping sequence, using control logic 450. The control logic triggers the burst generator 408 to generate the pulse burst at the appropriate time according to the value of the burst hopping sequence 407.

A burst generator 408 uses the PN sequences and the PPM slot to generate the pulse burst output data 440 at an appropriate time within the symbol duration.

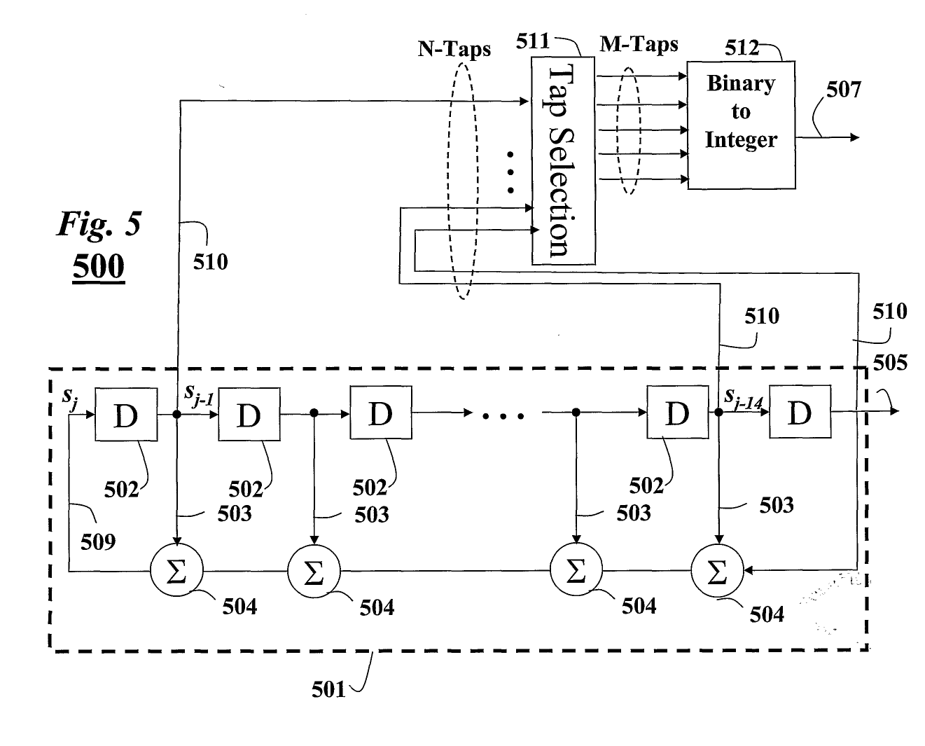

FIG. 5 shows the details of the PN sequence generator 500 that enables multiple PRF and modulation waveforms that have dynamically varying numbers of burst hopping slots from a single generator according to an embodiment of the invention.

The PN sequence generator 500 uses a linear feedback shift register 501 that includes a sequence of delay elements (D) 502, e.g., fifteen, and first taps 503 and second taps 510. The shift register generates both the polarity scrambling sequences 505 ands the time hopping sequences 507 for the pulse bursts 440.

The outputs of the individual delay elements 502, where the first taps 503 are present, are added 504, e.g., modulo-2) and fed back 509 to the input of the shift register 501. The operation of the shift register using only the first taps 503 is based on a well known design in the art, see Proakis, John G., Digital Communications, Third edition, New York, McGraw Hill, 1995. Polynomials describing the taps that can give maximal length PN polarity scrambling sequences are also described by Proakis. The first sequences 505 are used to scramble the polarities 403 in the pulse burst as shown in FIG. 4.

By using a second set of additional taps 510 and a conversion 512 from binary to integer numbers, time hopping sequence 507 for PPM can be obtained from the shift register 501 as well. In this case, we are not particularly concerned about which delay elements 502 are used to generate a maximal length burst time hopping sequence. We are more interested in allowing a variable number of possible burst hopping positions. Towards this end, we realize that the state of a length N shift register can represent any integer from 1 to 2^{N}. That is, the integer representation of a state of the shift register 501 is given by

h=sⱼ+sⱼ₋₁2¹+sⱼ₋₂2²+sⱼ₋₃2³+ . . . +s_{j-N}2^{N}, (7)

where s represents the state at each tap N.

Equation (7) indicates that we can use the states sⱼ's of the shift register to generate our time hopping sequences 507 for the pulse bursts. We do this by using a sufficient number M of taps 510, so that we can generate a number in the range from 1 to 2^{M}. We select M so that

2^{M}≧Nₛₗₒₜ. (8)

Here, we note that the number of burst hopping slots, Nₛₗₒₜ, need not be a power of two. In this case, certain states of the shift register may not correspond to a valid burst hopping slot index and additional processing may be required, such as truncation. It is more natural for the binary shift register and subsequent processing when the parameters of Equation (6) are selected so that Nₛₗₒₜ is a power of two. In this case, Nₛₗₒₜ is represented by 2^{M} and Equation (8) becomes

2^{M}=Nₛₗₒₜ. (9)

The burst hopping slot index can be determined from M of the N possible states of the shift register 501. This is shown in FIG. (5), were the second taps 510 from the delay elements 502 are set as inputs to a tap selection block 511. The tap selection block 511 selects, for example, the first M of the taps 510 and passes the selected taps to the binary to integer conversion block 512 to determine the time hopping index. In general, the number of taps that can be selected for the conversion to an integer value is a function of the number of slots. As an example to generate a burst hopping sequence over 4 possible hopping slots we set M=2 and to generate a sequence over 16 possible hopping slots we set M=4.

### EFFECT OF THE INVENTION

The embodiments of the invention provide a UWB transmitter with multiple time hopping sequences and polarity scrambling sequences selected from a single shift register. The invention can be used for modulation formats according to the IEEE 802.15.4a standard specification, particularly for modulation formats that use time hopping for bursts of pulses, in which a symbol is represented by short closely spaced sequence of pulses. The burst of pulses is hopped in time from symbol to symbol, in contrast to conventional impulse radio where individual pulses are time hopped.

Due to different possible modulation parameter options, a number of possible burst hopping slots vary depending on different modulation options. For example, some options allow four positions for the burst, while other options allow for sixteen possible positions.

As an advantage, the single shift register can generate size four or size sixteen time hopping sequences from the same generator, according to the modulation parameters. In addition, the shift register can also be used to generate sequences that modulate the polarity of the burst of pulses.

Although the invention has been described by way of examples of preferred embodiments, it is to be understood that various other adaptations and modifications may be made within the spirit and scope of the invention. Therefore, it is the object of the appended claims to cover all such variations and modifications as come within the true spirit and scope of the invention.

We claim:

1. A method for modulating an impulse radio signal, comprising:
modulating a polarity of a burst of pulses of an impulse radio signal using a first pseudo noise sequence generated by a shift register; and
modulating a position of the burst of pulses using a second pseudo noise sequence generated by the shift register.

2. The method of claim 1, in which the impulse radio signal is an ultra wide bandwidth signal.

3. The method of claim 1, in which the modulation uses both pulse position modulation and phase shift keying modulation.

4. The method of claim 1, in which the modulating of the polarity and the position are varied dynamically.

5. The method of claim 1, in which a length of the second pseudo noise sequence is varied dynamically according to modulation format parameters.

6. The method of claim 5, in which the format parameter is an average pulse repetition frequency.

7. The method of claim 6, in which the format parameter is a number of possible hopping positions are available within a modulation waveform.

8. The method of claim 7, in which a symbol duration, a chip duration, a number pulses per burst, and a pulse position modulation order define the number of possible hopping positions.

9. The method of claim 8, in which the chip duration is T_{c} and a number of pulses per burst is N_{burst}, and a duration of the burst of pulses is
T_{burst}=N_{burst}*T_{c}.

10. The method of claim 9, in which the average pulse repetition frequency for a symbol rate T_{sym} and the number of pulses per burst N_{burst} is
PRF=N_{burst}/T_{sym}.

11. The method of claim 1, further comprising:
encoding a symbol as the burst of pulses.

12. The method of claim 11, in which the encoding uses forward error correction.

13. The method of claim 1, in which the modulation of the polarity and the position depends on dynamically varying modulation format.

14. The method of claim 1, in which the shift register is a linear feedback shift register including a sequence of delay elements and a first set of taps and a second set of taps, and further comprising:
generating the first pseudo noise sequence from the first set of taps; and
generating the second pseudo noise sequence from the second set of taps.

15. The method of claim 14, in which outputs of the first set of taps are added and fed back to an input of the shift register.

16. The method of claim 15, in which outputs of the second set of taps are converted to an integer number to determine the second pseudo noise sequence.

17. The method of claim 16, in which an integer representation of a state of the shift register is
h=sⱼ+sⱼ₋₁2¹+sⱼ₋₂2²+sⱼ₋₃2³+ . . . +s_{j-N}2^{N}, where sⱼ represents the state at each tap N.

18. An apparatus for modulating an impulse radio signal, comprising:
a shift register configured to modulate a polarity of a burst of pulses of an impulse radio signal using a first pseudo noise sequence generated by the shift register, and to modulate a position of the burst of pulses using a second pseudo noise sequence generated by the shift register.

19. The apparatus of claim 18, in which the modulating of the polarity and the position are varied dynamically.

20. The apparatus of claim 18, in which a length of the second pseudo noise sequence is varied dynamically according to modulation format parameters.

21. The apparatus of claim 18, in which the modulation of the polarity and the position depends on dynamically varying modulation format.

22. The apparatus of claim 18, in which the shift register is a linear feedback shift register including a sequence of delay elements and a first set of taps and a second set of taps, and the first pseudo noise sequence is generated from the first set of taps, and the second pseudo noise sequence is generated from the second set of taps.

23. The apparatus of claim 22 in which outputs of the first set of taps are added and fed back to an input of the shift register.

24. The apparatus of claim 23, in which outputs of the second set of taps are converted to an integer number to determine the second pseudo noise sequence.

25. The apparatus of claim 22, in which an integer representation of a state of the shift register is
h=sⱼ+sⱼ₋₁2¹+sⱼ₋₂2²+sⱼ₋₃2³+ . . . +s_{j-N}2^{N}, where sⱼ represents the state at each tap N.
